(19) United States
(12) Patent Application Publication
(10) Pub. No.: US 2025/0159907 A1
(43) Pub. Date: May 15, 2025

(54) OXIDE SEMICONDUCTOR-BASED MEMORY DEVICE AND METHOD OF MANUFACTURING SAME

(71) Applicant: UIF (University Industry Foundation), Yonsei University, Seoul (KR)

(72) Inventors: Hyun Jae Kim, Seoul (KR); Sujin Lee, Seoul (KR); Min Seong Kim, Seoul (KR); Hyung Tae Kim, Seoul (KR); Young Wook Kim, Seoul (KR); Kyumin Kim, Seoul (KR)

(21) Appl. No.: 18/942,803

(22) Filed: Nov. 11, 2024

(30) Foreign Application Priority Data
Nov. 14, 2023 (KR) 10-2023-0156897
Jan. 15, 2024 (KR) 10-2024-0005846

(51) Int. Cl. H10B 63/00; H10N 70/00; H10N 70/20

(52) U.S. Cl. CPC H10B 63/80; H10N 70/026; H10N 70/041; H10N 70/25; H10N 70/253; H10N 70/257; H10N 70/8833

(57) ABSTRACT

Proposed is a method of manufacturing an oxide semiconductor-based memory device, the method including forming an insulating layer on a gate electrode, forming an oxygen-vacancy-inducing layer on the insulating layer, forming an oxide semiconductor thin film on the oxygen-vacancy-inducing layer, and performing annealing so that oxygen vacancies may be formed between the oxygen-vacancy-inducing layer and the oxide semiconductor thin film.

### STATEMENT REGARDING GOVERNMENT SPONSORED RESEARCH OR DEVELOPMENT

This present disclosure is derived from research conducted as part of the project of Electronic Components Industry Technology Development (R & D) (Project Unique Number: 141585955, Project Serial Number: 20010371, Specialized Institution for Project Management: Korea Planning and Evaluation Institute of Industrial Technology, Title of Project: Development of 4K-Level Flexible Display Devices and Panel Technology Through Pixel Formation Process Using Inkjet Printing Method, Supervising Institute: Samsung Display Co., Ltd., Research Period: Jan. 1, 2023 to Dec. 31, 2023), supported by the Ministry of Trade, Industry and Energy of the Republic of Korea.

Meanwhile, in all the aspects of the inventive concept, there is no property interest in the government of the Republic of Korea.

### CROSS REFERENCE TO RELATED APPLICATION

The present application claims priority to Korean Patent Application No. 10-2023-0156897, filed Nov. 14, 2023 and Korean Patent Application No. 10-2024-0005846, filed Jan. 15, 2024 the entire contents of which is incorporated herein for all purposes by this reference.

### BACKGROUND OF THE DISCLOSURE

### 1. Field of the Disclosure

The present disclosure relates to a semiconductor-based memory device. More specifically, the present disclosure relates to an oxide semiconductor-based memory device capable of having memory characteristics for optical and electrical signals.

### 2. Description of the Related Art

An oxide semiconductor-based memory device is a semiconductor device manufactured using oxides, and the oxide semiconductor-based memory device may mainly be applied to techniques for non-volatile memory types such as flash memory. Since oxide semiconductors offer high write/read speeds, which allows faster data access speeds, oxide semiconductors are widely used.

As the demand for low-cost, high-capacity storage devices increases, physical scaling of charge-trapping flash (CTF) type memory devices is required. However, there are also limitations to the physical scaling. In the case of memory devices using conventional oxide semiconductors, only the area below an initial state can be used, which presents a limitation for memory devices to function as multi-level memory devices. Accordingly, there is a need for a manufacturing technique for an oxide semiconductor-based memory device capable of implementing a multi-level memory device that can store a lot of data without scaling.

### SUMMARY OF THE DISCLOSURE

The purpose of the present disclosure is to provide an oxide semiconductor-based memory device capable of having memory characteristics for optical and electrical signals.

The method of manufacturing an oxide semiconductor-based memory device may include: forming an insulating layer on a gate electrode; forming an oxygen-vacancy-inducing layer on the insulating layer; forming an oxide semiconductor thin film on the oxygen-vacancy-inducing layer; and performing annealing so that oxygen vacancies may be formed between the oxygen-vacancy-inducing layer and the oxide semiconductor thin film.

Herein, the forming of the oxygen-vacancy-inducing layer may involve forming the oxygen-vacancy-inducing layer by sputtering using a first mask having holes of a first size. The forming of the oxide semiconductor thin film may involve forming the oxide semiconductor thin film by sputtering using a second mask having holes of a second size larger than the first size.

Herein, the forming of the oxygen-vacancy-inducing layer may involve forming the oxygen-vacancy-inducing layer by spin-coating. The forming of the oxide semiconductor thin film may involve forming the oxide semiconductor thin film with a size larger than the oxygen-vacancy-inducing layer by spin-coating.

Herein, the oxide semiconductor thin film may be formed to cover the oxygen-vacancy-inducing layer.

Herein, the annealing may be performed at a temperature of 300° C.

Herein, the annealing may be performed for 1 hour.

Herein, forming an electrode on the oxide semiconductor thin film may be further included.

Herein, the oxide semiconductor thin film may contain one or more selected from the group consisting of indium gallium zinc oxide (IGZO), zinc oxide (ZnO), indium zinc oxide (IZO), indium tin oxide (ITO), zinc tin oxide (ZTO), silicon indium zinc oxide (SIZO), gallium zinc oxide (GZO), hafnium indium zinc oxide (HIZO), zinc indium tin oxide (ZITO), and aluminum zinc tin oxide (AZTO).

Herein, the oxygen-vacancy-inducing layer may contain one or more selected from the group consisting of magnesium oxide (MgOx), aluminum oxide (AlOx), and hafnium oxide (HfOx).

Herein, the electrode may contain one or more selected from the group consisting of aluminum (Al), an aluminum alloy (Al alloy), tungsten (W), copper (Cu), nickel (Ni), chromium (Cr), molybdenum (Mo), titanium (Ti), and platinum (Pt), tantalum (Ta), and transparent conductive oxide (TCO).

The oxide semiconductor-based memory device according to one embodiment may include: an insulating layer formed on a gate electrode; an oxide semiconductor thin film formed on the insulating layer; and an oxygen-vacancy-inducing layer located between the insulating layer and the oxide semiconductor thin film and involved in the formation of oxygen vacancies by combining with oxygen of the oxide semiconductor thin film. The memory device may respond to an optical signal through a defect site caused by the oxygen vacancies, and may respond to an electrical signal by trapping/detrapping electrons through the oxygen vacancies.

Herein, the oxide semiconductor thin film may be formed to cover the oxygen-vacancy-inducing layer.

Herein, an electrode formed on the oxide semiconductor thin film may be further included.

Herein, the oxide semiconductor thin film may contain one or more selected from the group consisting of indium gallium zinc oxide (IGZO), zinc oxide (ZnO), indium zinc oxide (IZO), indium tin oxide (ITO), zinc tin oxide (ZTO), silicon indium zinc oxide (SIZO), gallium zinc oxide (GZO), hafnium indium zinc oxide (HIZO), zinc indium tin oxide (ZITO), and aluminum zinc tin oxide (AZTO).

Herein, the oxygen-vacancy-inducing layer may contain one or more selected from the group consisting of magnesium oxide (MgOx), aluminum oxide (AlOx), and hafnium oxide (HfOx).

Herein, the electrode may contain one or more selected from the group consisting of aluminum (Al), an aluminum alloy (Al alloy), tungsten (W), copper (Cu), nickel (Ni), chromium (Cr), molybdenum (Mo), titanium (Ti), platinum (Pt), tantalum (Ta), and transparent conductive oxide (TCO).

The present disclosure according to one embodiment can provide an oxide semiconductor-based memory device capable of having memory characteristics for optical and electrical signals.

### BRIEF DESCRIPTION OF THE DRAWINGS

FIG. 1 shows a diagram illustrating an oxide semiconductor-based memory device according to one embodiment;

FIGS. 2, 3, 4, and 5 show a diagram illustrating a method of manufacturing the oxide semiconductor-based memory device according to another embodiment;

FIGS. 6, 7, 8, and 9 show electrical characteristic test results of a conventional oxide semiconductor-based memory device and the oxide semiconductor-based memory device of the present disclosure;

FIGS. 10 and 11 show the results of experiments on light response characteristics of the conventional oxide semiconductor-based memory device and the oxide semiconductor-based memory device of the present disclosure;

FIGS. 12 and 13 show the results of an experiment on the memory characteristics of the oxide semiconductor-based memory device of the present disclosure for simultaneous electrical and optical signals; and

FIG. 14 shows a diagram illustrating the characteristics of the oxide semiconductor-based memory device of the present disclosure as a multi-level memory device.

### DETAILED DESCRIPTION OF EXEMPLARY EMBODIMENTS

The embodiments described in this specification are intended to clearly explain the spirit of the present disclosure to those skilled in the art. The present disclosure is not limited to the embodiments described in this specification, and the scope of the present disclosure should be construed to include modifications or variations that do not depart from the spirit of the present disclosure.

The terms used in this specification are general terms that are currently widely used as much as possible in consideration of their functions in the present disclosure. However, this may vary depending on the intention of those skilled in the art in the technical field to which the present disclosure pertains, precedents, or the emergence of new techniques. However, when a specific term is defined and used with an arbitrary meaning, the meaning of the term will be described separately. Therefore, the terms used in this specification should be interpreted based on the actual meaning of the term and the overall content of this specification, not just the name of the term.

The drawings attached to this specification are intended to easily explain the present disclosure, and the shapes shown in the drawings may be exaggerated as necessary to aid understanding of the present disclosure, so the present disclosure is not limited by the drawings.

In this specification, when it is determined that a detailed description of a known configuration or function related to the present disclosure may obscure the gist of the present disclosure, the detailed description thereof will be omitted as necessary.

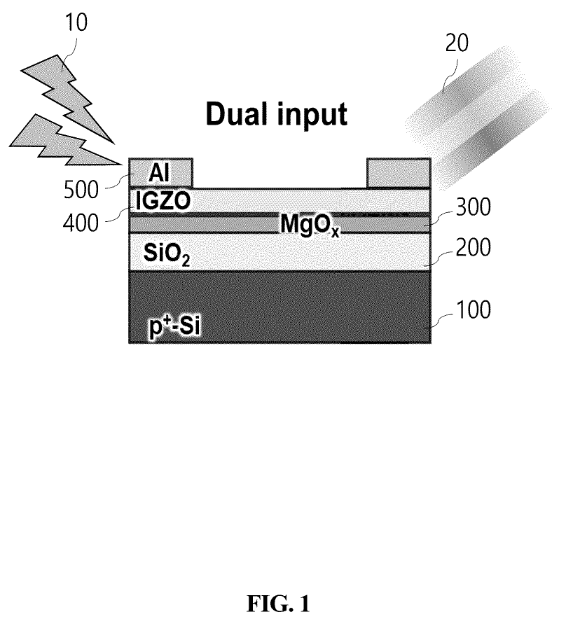

FIG. 1 shows a diagram illustrating an oxide semiconductor-based memory device according to one embodiment.

Referring to FIG. 1, an oxide semiconductor-based memory device according to one embodiment may include a substrate (not shown), a gate electrode 100, an insulating layer 200, an oxygen-vacancy-inducing layer 300, an oxide semiconductor thin film 400, and an electrode 500.

The substrate may play a role in supporting various components as a base of an oxide semiconductor. For example, the substrate may include any material selected from the group consisting of glass, polyimide-based polymer, polyester-based polymer, silicone-based polymer, acrylic-based polymer, polyolefin-based polymer, or copolymers thereof.

Specifically, the substrate may include one or more selected from the group consisting of polyester, polyvinyl, polycarbonate, polyethylene, polyacetate, polyimide, polyethersulfone, polyacrylate, polyethylene naphthalate, and polyethyleneterephthalate.

Herein below, the oxide semiconductor-based memory device formed on the substrate will be described. However, without being limited to this, the oxide semiconductor-based memory device may be manufactured without the substrate.

The gate electrode 100 may be formed on the substrate. Specifically, the gate electrode 100 may be formed on the substrate using one or more selected from the group consisting of vacuum deposition, chemical vapor deposition, physical vapor deposition, atomic layer deposition, organic metal chemical vapor deposition, plasma chemical deposition, molecular beam growth, hydrogen vapor growth method, sputtering, spin coating, dip coating, and zone casting but the method is not limited thereto.

The gate electrode 100 may be made of any one selected from the group consisting of molybdenum (Mo), aluminum (Al), chromium (Cr), gold (Au), titanium (Ti), nickel (Ni), neodymium (Nd), copper (Cu), transparent conductive oxide (TCO), or a combination thereof, but the composition of the gate electrode is not limited thereto. FIG. 1 shows that the gate electrode 100 is made of a p+-Si material, but the composition of the gate electrode is not limited thereto.

The insulating layer 200 may be formed on the gate electrode 100. The insulating layer 200 may block an electrical connection between the gate electrode 100 and other metal layers. Specifically, the insulating layer 200 may serve to block the electrical connection between the gate electrode 100 and the oxygen-vacancy-inducing layer 300.

The insulating layer 200 may be formed on the gate electrode 100 using one or more selected from the group consisting of vacuum deposition, chemical vapor deposition, physical vapor deposition, atomic layer deposition, organic metal chemical vapor deposition, plasma chemical deposition, molecular beam growth, hydrogen vapor growth method, sputtering, spin coating, dip coating, and zone casting, but the method is not limited thereto. Preferably, to avoid process complexity, the same method as that of forming the gate electrode 100 may be used.

The insulating layer 200 may contain an organic material such as silicon oxide (SiOx), silicon nitride (SiNx), titanium oxide (TiOx), an inorganic material such as hafnium oxide (HfOx) or polyvinyl alcohol (PVA), polyvinylpyrrolidone (PVP), and polymethyl methacrylate (PMMA), but the composition of the insulating layer is not limited thereto. Although FIG. 1 shows that the insulating layer 200 contains silicon oxide (SiO₂), but the composition of the insulating layer is not limited thereto.

The oxygen-vacancy-inducing layer 300 may be formed on the insulating layer 200. The specific formation process of the oxygen-vacancy-inducing layer 300 will be described again after the description of the oxide semiconductor thin film 400.

Although FIG. 1 shows that the oxygen-vacancy-inducing layer 300 contains MgOx, the composition of the oxygen-vacancy-inducing layer is not limited thereto. For example, the oxygen-vacancy-inducing layer 300 may contain a material with a low standard electrode potential (SEP). For example, the oxygen-vacancy-inducing layer 300 may contain one or more selected from the group consisting of magnesium oxide (MgOx), aluminum oxide (AlOx), and hafnium oxide (HfOx), but the composition of the oxygen-vacancy-inducing layer is not limited thereto. The oxygen-vacancy-inducing layer may contain one or more other metals that have a strong bonding force with oxygen. The oxygen-vacancy-inducing layer 300 may also be referred to as a metal layer, a first oxide semiconductor thin film, or a lower oxide semiconductor thin film as an oxide layer.

The oxide semiconductor thin film 400 may be formed on the oxygen-vacancy-inducing layer. The oxide semiconductor thin film 400 may be deposited through a sputtering process. The oxide semiconductor thin film 400 may contain one or more selected from the group consisting of indium gallium zinc oxide (IGZO), zinc oxide (ZnO), indium zinc oxide (IZO), indium tin oxide (ITO), zinc tin oxide (ZTO), silicon indium zinc oxide (SIZO), gallium zinc oxide (GZO), hafnium indium zinc oxide (HIZO), zinc indium tin oxide (ZITO), and aluminum zinc tin oxide (AZTO), but the composition of the oxide semiconductor thin film is not limited thereto. The oxide semiconductor thin film 400 may also be referred to as a second oxide semiconductor thin film or an upper oxide semiconductor thin film.

Since the oxygen-vacancy-inducing layer 300 has a stronger bonding force with oxygen than the oxide semiconductor thin film 400, the oxygen-vacancy-inducing layer may bond with oxygen on the oxide semiconductor thin film 400. Accordingly, oxygen vacancies may be formed at an interface between the oxygen-vacancy-inducing layer 300 and the oxide semiconductor thin film 400.

After the oxide semiconductor thin film 400 is deposited on an insulating layer, an annealing process may be performed to create the oxygen-vacancy-inducing layer 300. That is, the oxygen-vacancy-inducing layer 300 and the oxide semiconductor thin film 400 may be electrically and optically activated through heat treatment.

Specifically, annealing may be performed over an oxide semiconductor-based material including the oxide semiconductor thin film 400 formed on the oxygen-vacancy-inducing layer. Through annealing, the oxygen-vacancy-inducing layer may be involved in the formation of more oxygen vacancies than before annealing. Additionally, the oxide semiconductor thin film may be activated by performing annealing.

Through oxygen vacancies, the oxide semiconductor-based memory device of the present disclosure may respond to the optical signal as well as the electrical signal. Specifically, when the optical signal is input, a signal corresponding to the optical signal may be output through a defect site caused by the oxygen vacancies. Additionally, when the electrical signal is input, a signal corresponding to the electrical signal may be output by trapping/detrapping electrons through oxygen vacancies. Therefore, the oxide semiconductor-based memory device of the present disclosure may use oxygen vacancies formed between the oxygen-vacancy-inducing layer 300 and the oxide semiconductor thin film 400, thereby the oxide semiconductor-based memory device of the present disclosure may be a memory device capable of simultaneously controlling optical and electrical signals.

The electrode 500 may be formed on the oxide semiconductor thin film 400. The electrode 500 may be deposited on the oxide semiconductor thin film 400 through a sputtering process using a mask, but the method is not limited thereto.

The electrode 500 may contain one or more selected from the group consisting of aluminum (Al), an aluminum alloy (Al alloy), tungsten (W), copper (Cu), nickel (Ni), chromium (Cr), molybdenum (Mo), titanium (Ti), platinum (Pt), tantalum (Ta), and transparent conductive oxide (TCO), but the composition of the electrode is not limited thereto. Although FIG. 1 shows that the electrode 500 is made of the p+-Si material, but the composition of the electrode is not limited thereto.

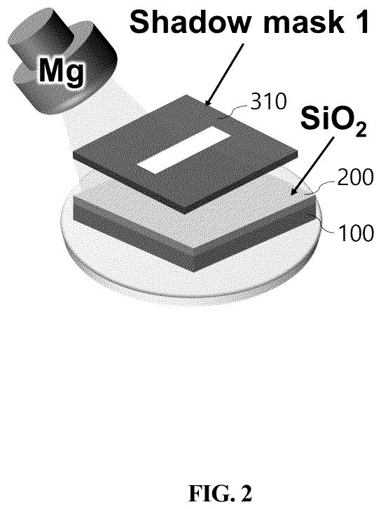

FIGS. 2 to 5 show a diagram illustrating a method of manufacturing the oxide semiconductor-based memory device according to another embodiment.

Referring to FIG. 2, the method of manufacturing an oxide semiconductor-based memory device according to another embodiment may include forming the gate electrode 100 on the substrate. For example, the forming of the gate electrode 100 may involve depositing the p+-Si material on the substrate using a sputtering process or a spin coating process but is not limited thereto.

The method of manufacturing an oxide semiconductor-based memory device according to a further embodiment may include forming the insulating layer 200 on the gate electrode 100. For example, the forming of the insulating layer 200 may involve depositing a SiO₂ material on the substrate using a sputtering process or a spin coating process but is not limited thereto.

The method of manufacturing an oxide semiconductor-based memory device according to a yet further embodiment may include forming the oxygen-vacancy-inducing layer on the insulating layer 200. For example, the forming of the oxygen-vacancy-inducing layer may involve depositing magnesium oxide (MgOx) through a sputtering process using a first mask 310 having holes of the first size, but is not limited thereto.

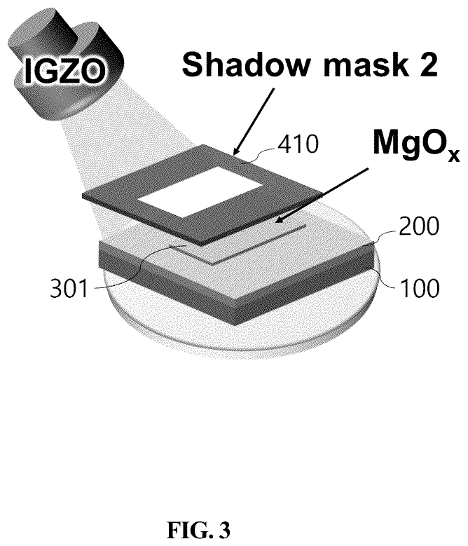

Referring to FIG. 3, the method of manufacturing an oxide semiconductor-based memory device according to a still yet further embodiment may include forming the oxide semiconductor thin film on the oxygen-vacancy-inducing layer 300. For example, the forming of an oxide semiconductor thin film may involve depositing IGZO through a sputtering process using a second mask 410 having holes of a second size but is not limited thereto.

At this point, the second size may be larger than the first size, which is the size of the holes in the first mask. Since the oxygen-vacancy-inducing layer contains a metal material that has a high bonding force with oxygen, bonding may occur with external oxygen rather than oxygen contained in the oxide semiconductor thin film. To prevent this, the oxide semiconductor thin film may be formed to cover the oxygen-vacancy-inducing layer 300.

That is, the second size, which is the size of the holes in the second mask that determines the deposition size of the oxide semiconductor thin film, may be larger than the first size, which is the size of the holes in the first mask that determines the deposition size of the oxygen-vacancy-inducing layer 300. Accordingly, the oxide semiconductor thin film may be manufactured to cover the oxygen-vacancy-inducing layer 300 so that the oxygen-vacancy-inducing layer 300 is not exposed to the outside.

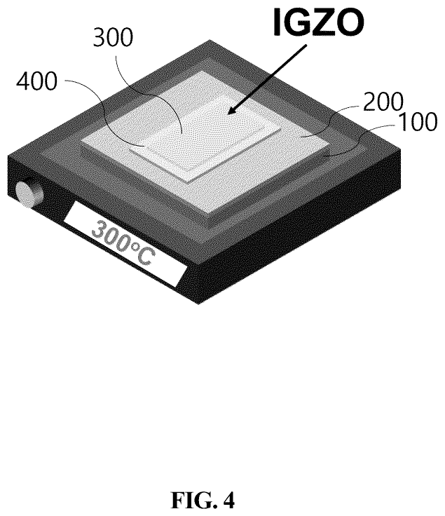

Referring to FIG. 4, the method of manufacturing an oxide semiconductor-based memory device according to a still yet further embodiment may include annealing the oxygen-vacancy-inducing layer 300 and the oxide semiconductor thin film 400. At this point, annealing may be performed at a temperature of 300° C. for 1 hour, but the temperature is not limited thereto. Through the annealing process, the oxygen-vacancy-inducing layer 300 may be involved in the formation of more oxygen vacancies. FIG. 4 is a perspective view showing the oxygen-vacancy-inducing layer 300 covered by the oxide semiconductor thin film 400. However, when viewed with the naked eye, the oxygen-vacancy-inducing layer 300 may not be visible as the oxygen-vacancy-inducing layer is covered by the oxide semiconductor thin film 400.

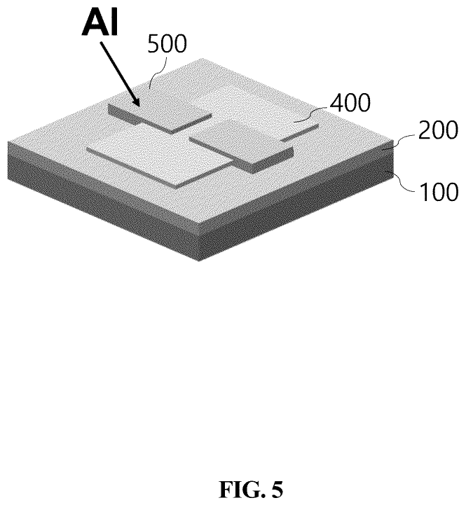

Referring to FIG. 5, the method of manufacturing an oxide semiconductor-based memory device according to a still yet further embodiment may include forming the electrode 500 on the oxide semiconductor thin film 400. For example, the electrode 500 may be formed using a mask and a metal material, but the method is not limited thereto. The electrode 500 may include a first electrode and a second electrode that are spaced apart from each other. At this point, the first electrode may be a source electrode, and the second electrode may be a drain electrode.

By the manufacturing method of FIGS. 2 to 5, the manufactured oxide semiconductor-based memory device may include oxygen vacancies formed between the oxygen-vacancy-inducing layer 300 and the oxide semiconductor thin film 400, thereby the oxide semiconductor-based memory device may be capable of simultaneously controlling optical and electrical signals. Accordingly, the memory device of the present disclosure may use three or more states than the conventional memory device, thereby the memory device of the present disclosure may be a multi-level memory device (device) and store more data.

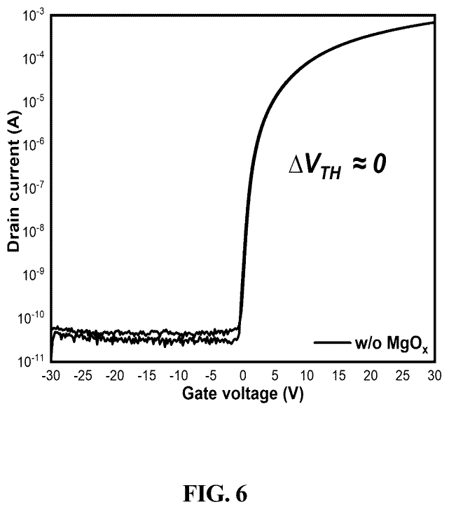

FIGS. 6 to 9 show electrical characteristic test results of a conventional oxide semiconductor-based memory device and the oxide semiconductor-based memory device of the present disclosure.

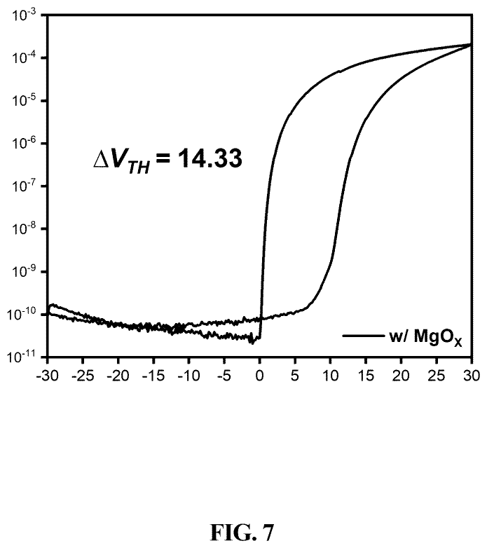

FIG. 6 shows a graph showing the hysteresis characteristic of a conventional oxide semiconductor-based memory device. FIG. 7 shows a graph showing the hysteresis characteristics of the oxide semiconductor-based memory device of the present disclosure.

Referring to FIG. 6, the change in V_TH in the conventional memory device is about 0. On the other hand, the memory device of the present disclosure has a change in V_TH of about 14.33. From this, it was confirmed that oxygen vacancies were formed, and that electrical control was possible through trapping/detrapping of electrons.

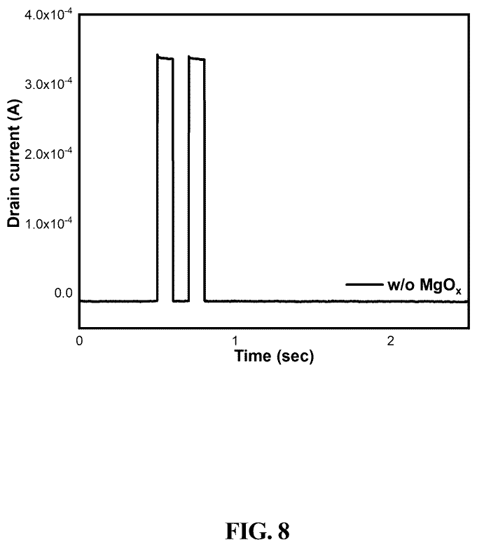

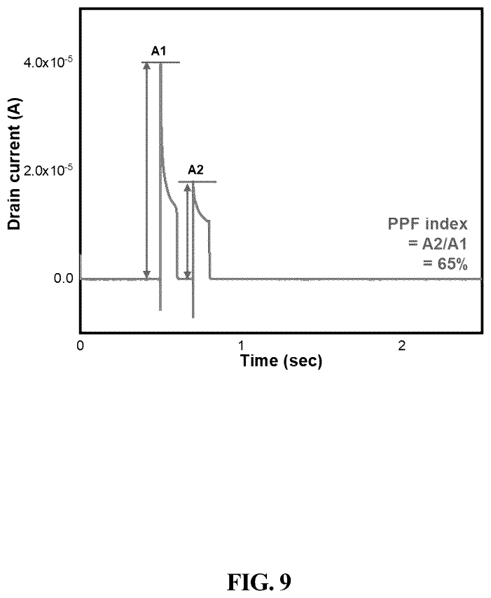

FIG. 8 shows a graph showing the PPF characteristics of a conventional oxide semiconductor-based memory device. FIG. 9 shows a graph showing the PPF characteristics of the oxide semiconductor-based memory device of the present disclosure.

Referring to FIGS. 8 and 9, it was confirmed that the present disclosure trapped 35% of electrons in the oxygen-vacancy-inducing layer, thereby enabling electrical control, unlike the conventional art.

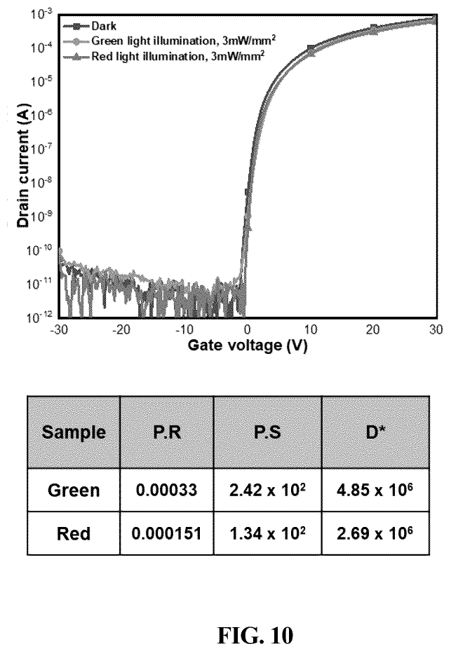

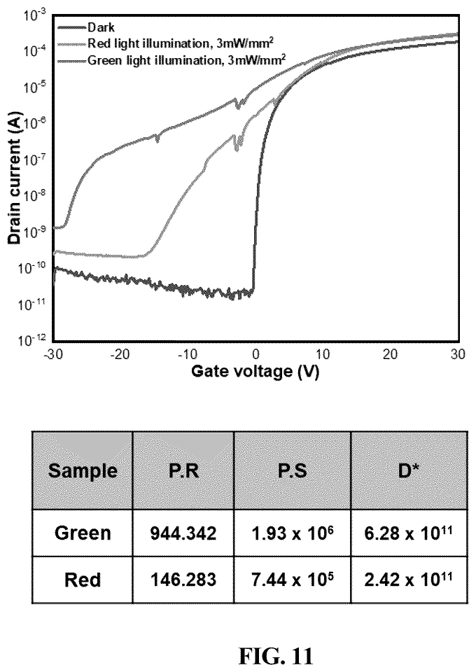

FIGS. 10 and 11 show the results of experiments on light response characteristics of the conventional oxide semiconductor-based memory device and the oxide semiconductor-based memory device of the present disclosure.

FIG. 10 shows a graph showing the optical response of a conventional oxide semiconductor-based memory device. FIG. 11 shows a graph showing the optical response of the oxide semiconductor-based memory device of the present disclosure.

Referring to FIGS. 10 and 11, it was confirmed that the present disclosure responded to both red light and green light, unlike the conventional art. From this, it was confirmed that the memory device of the present disclosure had characteristics that responded to visible light, thereby light control was possible.

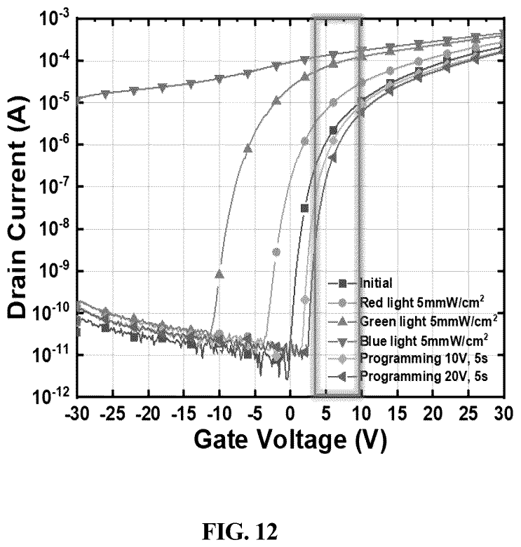

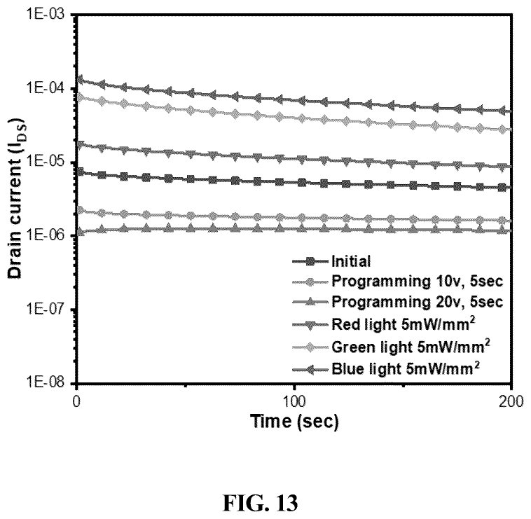

FIGS. 12 and 13 show the results of an experiment on the memory characteristics of the oxide semiconductor-based memory device of the present disclosure for simultaneous electrical and optical signals. FIGS. 12 and 13 show the results of experiments in which programming was performed for 5 seconds to check memory characteristics depending on electrical and optical signal inputs for the oxide semiconductor-based memory device of the present disclosure. Specifically, the electrical signal input was programmed at 10V and 20V, and the optical signal input was set to 5 mW/mm² for red, green, and blue light.

Referring to FIG. 12, it was confirmed that the signals were shifted to the right compared to the initial state with respect to the electrical signal input. Additionally, it was confirmed that the signals were shifted to the left compared to the initial state with respect to optical signal input. From this, it was confirmed that the memory device of the present disclosure responded in both the left and right areas based on the initial state. Additionally, the memory device of the present disclosure responded to a wide range of gate voltages and might use a wider range of areas than conventional devices. Thus, the memory device of the present disclosure may store more data as a multi-level memory device.

Referring to FIG. 13, it was confirmed that the signals were shifted downward compared to the initial state with respect to the electrical signal input. Additionally, it was confirmed that the signals were shifted upward compared to the initial state with respect to optical signal input. From this, it was confirmed that the memory device of the present disclosure responded in both the lower region and the upper region based on the initial state. Thus, the memory device of the present disclosure may store more data as a multi-level memory device.

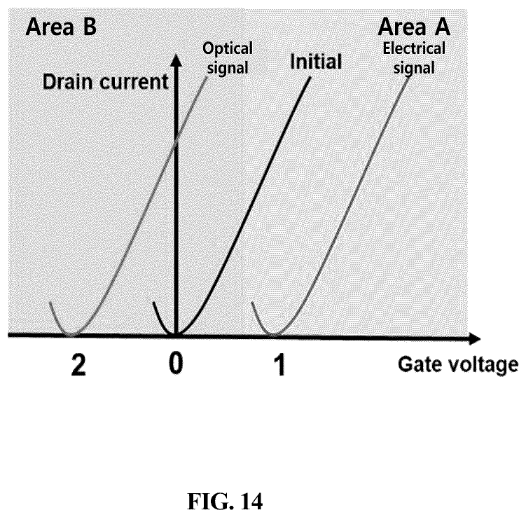

FIG. 14 shows a diagram illustrating the characteristics of the oxide semiconductor-based memory device of the present disclosure as a multi-level memory device.

Referring to FIG. 14, it was confirmed that the present disclosure may use three or more states, unlike the conventional art. Specifically, conventional memory device may use only two states by using only the electrical signal as input or only the optical signal as input.

On the other hand, the memory device of the present disclosure may use both electrical and optical signals as input, and may have three or more states. Specifically, it was confirmed that, based on the initial state (Initial) in FIG. 14, when the optical signal was input, the graph shifted to the left, and when the electrical signal was input, the graph was shifted to the right. Accordingly, it was confirmed that the memory device of the present disclosure had three or more states (state 0, state 1, and state 2) that may be used.

In addition, the memory device of the present disclosure was able to use an area A (corresponding to an area in which the graph for the electrical signal in FIG. 12 was shifted to the right from the initial state and an area in which the graph for the electrical signal in FIG. 13 was shifted downward from the initial state) of FIG. 14, as well as the memory device of the present disclosure was able to use an area B (corresponding to an area in which the graph for the optical signal in FIG. 12 was shifted to the left from the initial state and an area in which the graph for the electrical signal in FIG. 13 was shifted upward from the initial state). Thus, the memory device of the present disclosure may implement a multi-level device compared to the conventional art, thereby larger amounts of data may be stored.

As described above, although the embodiments have been described with limited embodiments and drawings, various modifications and variations may be made by those skilled in the art from the above description. For example, the described techniques are performed in a different order than the described method, and/or components of the described system, structure, device, and circuit are combined or combined in a different form than the described method, or other components are used. Alternatively, appropriate results may be achieved even if substituted or substituted by an equivalent.

Therefore, other implementations, other embodiments, and equivalents of the claims also fall within the scope of the claims described below.

What is claimed is:

1. A method of manufacturing an oxide semiconductor-based memory device, the method comprising:
forming an insulating layer on a gate electrode;
forming an oxygen-vacancy-inducing layer on the insulating layer;
forming an oxide semiconductor thin film on the oxygen-vacancy-inducing layer; and
performing annealing so that oxygen vacancies are formed between the oxygen-vacancy-inducing layer and the oxide semiconductor thin film.

2. The method of claim 1, wherein the forming of the oxygen-vacancy-inducing layer comprises forming the oxygen-vacancy-inducing layer by sputtering using a first mask having holes of a first size, and
the forming of an oxide semiconductor thin film comprises forming an oxide semiconductor thin film by sputtering using a second mask having holes of a second size larger than the first size.

3. The method of claim 1, wherein the forming of the oxygen-vacancy-inducing layer comprises forming the oxygen-vacancy-inducing layer by spin-coating, and
the forming of the oxide semiconductor thin film comprises forming the oxide semiconductor thin film with a size larger than the oxygen-vacancy-inducing layer by spin-coating.

4. The method of claim 2, wherein the oxide semiconductor thin film is formed to cover the oxygen-vacancy-inducing layer.

5. The method of claim 1, wherein the annealing is performed at a temperature of 300° C.

6. The method of claim 1, wherein the annealing is performed for 1 hour.

7. The method of claim 1, further comprising:
forming an electrode on the oxide semiconductor thin film.

8. The method of claim 1, wherein the oxide semiconductor thin film contains one or more selected from the group consisting of indium gallium zinc oxide (IGZO), zinc oxide (ZnO), indium zinc oxide (IZO), indium tin oxide (ITO), zinc tin oxide (ZTO), silicon indium zinc oxide (SIZO), gallium zinc oxide (GZO), hafnium indium zinc oxide (HIZO), zinc indium tin oxide (ZITO), and aluminum zinc tin oxide (AZTO).

9. The method of claim 1, wherein the oxygen-vacancy-inducing layer contains one or more selected from the group consisting of magnesium oxide (MgOx), aluminum oxide (AlOx), and hafnium oxide (HfOx).

10. The method of claim 7, wherein the electrode contains one or more selected from the group consisting of aluminum (Al), an aluminum alloy (Al alloy), tungsten (W), copper (Cu), nickel (Ni), chromium (Cr), molybdenum (Mo), titanium (Ti), platinum (Pt), tantalum (Ta), and transparent conductive oxide (TCO).

11. An oxide semiconductor-based memory device, comprising:
an insulating layer formed on a gate electrode;
an oxide semiconductor thin film formed on the insulating layer; and
an oxygen-vacancy-inducing layer located between the insulating layer and the oxide semiconductor thin film and involved in the formation of oxygen vacancies by combining with oxygen of the oxide semiconductor thin film,
wherein the memory device responds to an optical signal through a defect site caused by the oxygen vacancies, and responds to an electrical signal by trapping/detrapping electrons through the oxygen vacancies.

12. The memory device of claim 11, wherein the oxide semiconductor thin film is formed to cover the oxygen-vacancy-inducing layer.

13. The memory device of claim 11, further comprising:
an electrode formed on the oxide semiconductor thin film.

14. The memory device of claim 11, wherein the oxide semiconductor thin film contains one or more selected from the group consisting of indium gallium zinc oxide (IGZO), zinc oxide (ZnO), indium zinc oxide (IZO), indium tin oxide (ITO), zinc tin oxide (ZTO), silicon indium zinc oxide (SIZO), gallium zinc oxide (GZO), hafnium indium zinc oxide (HIZO), zinc indium tin oxide (ZITO), and aluminum zinc tin oxide (AZTO).

15. The memory device of claim 11, wherein the oxygen-vacancy-inducing layer contains one or more selected from the group consisting of magnesium oxide (MgOx), aluminum oxide (AlOx), and hafnium oxide (HfOx).

16. The memory device of claim 13, wherein the electrode contains one or more selected from the group consisting of aluminum (Al), an aluminum alloy (Al alloy), tungsten (W), copper (Cu), nickel (Ni), chromium (Cr), molybdenum (Mo), titanium (Ti), platinum (Pt), tantalum (Ta), and transparent conductive oxide (TCO).
